(19) United States
(12) Patent Application Publication
(10) Pub. No.: US 2025/0069905 A1
(43) Pub. Date: Feb. 27, 2025

(54) MULTI-WAFER SCRUBBING DEVICE

(71) Applicant: HANGZHOU SIZONE ELECTRONIC TECHNOLOGY INC, Zhejiang (CN)

(72) Inventors: Qi YIN, Zhejiang (CN); Xiaoyu XU, Zhejiang (CN)

(73) Assignee: HANGZHOU SIZONE ELECTRONIC TECHNOLOGY INC, Zhejiang (CN)

(21) Appl. No.: 18/720,664

(22) PCT Filed: Nov. 9, 2022
(86) PCT No.: PCT/CN2022/130778

§ 371 Date: Jun. 17, 2024

(30) Foreign Application Priority Data
Oct. 19, 2021 (CN) 202111215889.1

(51) Int. Cl. H01L 21/67; A46B 13/00; A46B 13/02

(52) U.S. Cl. CPC H01L 21/67046; A46B 13/001; A46B 13/02; A46B 2200/3073

(57) ABSTRACT

Disclosed in the present invention is a multi-wafer scrubbing device, comprising a box body. Multiple compartments are provided in the box body; the bottoms of the multiple compartments are connected; a support wheel system and a scrubbing system are provided inside each compartment; the scrubbing system comprises a group of roller brush units; the roller brush units can get close to each other to scrub wafers or away from each other to take out the wafers; multiple scrubbing systems are connected by means of an opening and closing drive mechanism; the opening and closing drive mechanism is used for simultaneously driving multiple groups of roller brush units to get close to or away from each other.

### TECHNICAL FIELD

The invention belongs to the field of production of semiconductor integrated circuit chips, and in particular relates to a multi-wafer scrubbing device.

### DESCRIPTION OF RELATED ART

Chemical mechanical polishing (CMP) is a processing technology in the integrated circuit manufacturing. With the advancement of technology, the requirements for processing technology will increase accordingly. In the meanwhile, CMP is a wet process during wafer processing. A large amount of abrasive fluid and different chemical reagents are used throughout the process. Therefore, before entering the next process, wafers need to be cleaned and dried at the end of the process to remove particles attached to the surfaces of the wafers.

In existing integrated circuit equipment, wafers are inserted into a scrubbing box, and a support wheel system and a roller brush system work together to scrub the surfaces of the wafers. thereby ensuring that no particles remain on the surfaces of the wafers. The wafers are placed on a plurality of support wheels in the scrubbing box, the support wheels are all tangent to the circumference of the wafers, and the wafers are driven to rotate under the action of a support wheel drive system. The roller brush system consists of two rotating roller brushes, which get close to each other and come into contact with both sides of the wafer during operation.

The support wheel system and the roller brush system work together to ensure that the surfaces of the wafers are completely cleaned; however, the scrubbing box is complex in overall structure and takes up a large equipment space. Scrubbing devices currently used can only clean a single wafer in the scrubbing box, which takes a long time and seriously affects production efficiency. Using multiple sets of scrubbing boxes to clean wafers at the same time requires a very large space, which is not conducive to reducing the equipment size. In order to improve the wafer scrubbing efficiency and reduce the space size of equipment, the structure of the scrubbing devices needs to be improved.

### SUMMARY

In order to overcome the shortcomings of the prior art, the invention provides a multi-wafer scrubbing device that can simultaneously scrub multiple wafers in the same box body with high cleaning efficiency and takes up smaller equipment space.

A technical solution adopted by the invention to solve the technical problem is: a multi-wafer scrubbing device, comprising a box body, wherein multiple compartments are provided in the box body, the bottoms of the multiple compartments are connected, a support wheel system and a scrubbing system are provided inside each compartment, the scrubbing system comprises a group of roller brush units, and the roller brush units can get close to each other to scrub wafers or away from each other to take out the wafers; multiple scrubbing systems are connected by means of an opening and closing drive mechanism; the opening and closing drive mechanism is used for simultaneously driving multiple groups of roller brush units to get close to or away from each other.

Further, the roller brush unit comprises two crossbars arranged in parallel, first connecting plates connected to two ends of one crossbar, and second connecting plates connected to two ends of the other crossbar, and the first connecting plates and the second connecting plates are configured to install roller brushes; driven by the opening and closing drive mechanism, the two first connecting plates and the two second connecting plates of different groups of roller brush units are all opened or closed in V-shape synchronously.

Further, the opening and closing drive mechanism comprises a power source, a first driving unit connected to the power source, a second driving unit, and a third driving unit; the first driving unit is respectively connected to the second connecting plates and the first connecting plates of an adjacent roller brush unit; the second driving unit is configured to drive the first connecting plates and the second connecting plates of the same group of roller brush units to open or close; the third driving unit is provided between adjacent rolling brush units that are not connected to the power source and is configured to drive the second connecting plates and the first connecting plates of the adjacent rolling brush units to open or close.

Further, the first driving unit at least comprises a turntable that can be driven by the power source to rotate circumferentially, and connecting rods; two connecting rods are provided, one ends of the two connecting rods are directly or indirectly connected to the turntable, and the other ends of the two connecting rods are directly or indirectly connected to the first connecting plates and the second connecting plates of the adjacent roller brush unit respectively

Further, each of the two connecting rods and the turntable are connected by means of a third transfer column, the first connecting plate and one connecting rod are connected by means of a first transfer column, and the second connecting plate and the other connecting rod are connected by means of a second transfer column.

Further, the two third transfer columns are arranged in a radial direction of the turntable; in an initial state, the two third transfer columns are located vertically between the two connecting plates, and the connecting rods and the third transfer columns are connected obliquely.

Further, the second driving unit comprises a first gear provided at the bottom of the first connecting plate and a second gear provided at the bottom of the second connecting plate, and the first gear and the second gear mesh with each other for transmission.

Further, in a case where at least two third driving units are provided, the third driving units are arranged one above the other alternately.

Further, notches are formed in both the second connecting plates and the first connecting plates of adjacent roller brush units to form an avoidance space.

Further, the tops of the multiple compartments are connected and the multiple compartments share an exhaust system and a drainage system; each compartment is internally provided with a spray system.

The invention provides a scrubbing device capable of cleaning multiple wafers, and the implementation structure of the device can simultaneously scrub multiple wafers in a scrubbing box. The scrubbing box body is extended and divided into multiple independent compartments. Each compartment has an independent support wheel system, roller brush system and spray system. The invention can not only ensure the cleanliness of scrubbed wafers, but also effectively utilize the equipment space and improve the cleaning efficiency.

The merits of the invention are as follows: 1) multiple groups of roller brush units are integrated into a same box body, thereby greatly shortening the distance between stations and effectively improving production efficiency per unit volume. 2) By means of the independent support wheel system, scrubbing system and spray system, different wafers can be scrubbed separately or simultaneously, thereby improving efficiency and also ensuring flexibility. 3) The box body may have two compartments, three compartments or four compartments, etc., so the quantity of the compartments can be highly customized and the range of application is wide. 4) In the same box body, the bottoms of different compartments can be connected so that multiple stations can share a set of drainage pipelines, thereby simplifying a drainage system and further reducing the internal space of equipment. 5) The integrated scrubbing box body shares multiple parts such as partitions, bottom plates, which greatly reduces the number of parts, saves material costs, and reduces assembly workload. 6) By sharing one opening and closing drive mechanism, different roller brush units can be opened or closed synchronously, thereby saving equipment space and reducing procurement costs. 7) The multi-wafer brushing device can have a symmetrical structure, which is conducive to equipment arrangement and facilitates the connection of electrical and gas-liquid lines.

### BRIEF DESCRIPTION OF THE DRAWINGS

FIG. 1 is a perspective diagram of the invention without a box body.

FIG. 2 is a partially perspective diagram of the invention.

FIG. 3 is a partially schematic diagram of an assembly of an opening and closing drive mechanism and roller brush units according to the invention.

FIG. 4 is another partially schematic diagram of the assembly of the opening and closing drive mechanism and the roller brush units according to the invention.

FIG. 5 is a partially schematic diagram of the assembly of the opening and closing drive mechanism and the roller brush units according to the invention when first connecting plates and second connecting plates are opened.

FIG. 6 is a perspective diagram of a first driving unit according to the invention.

FIG. 7 is another perspective diagram of the first driving unit according to the invention.

FIG. 8 is yet another perspective diagram of the first driving unit according to the invention.

### DESCRIPTION OF THE EMBODIMENTS

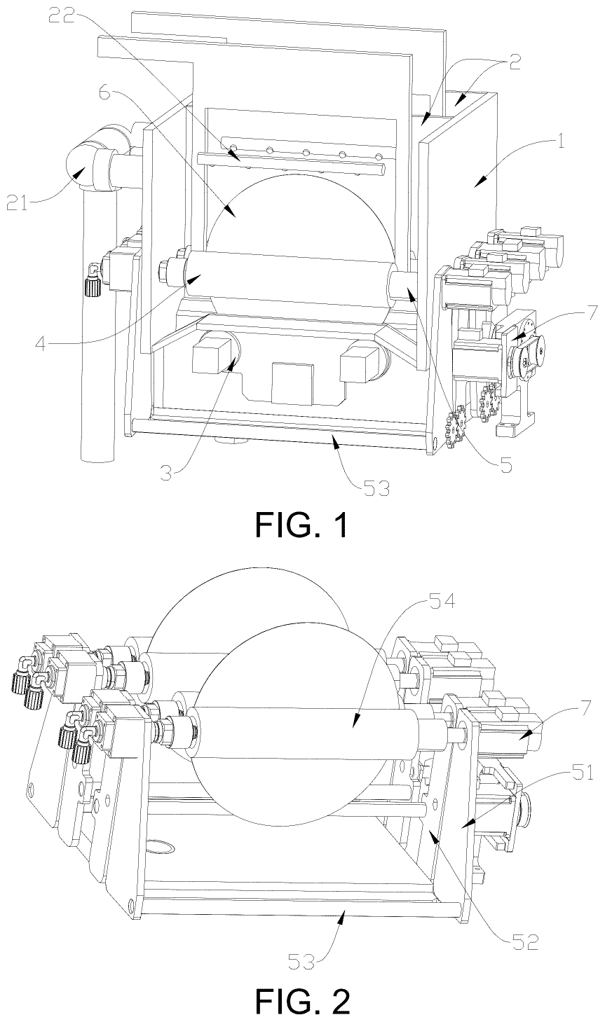

In order to make those skilled in the art better understand the technical solutions of the invention, the technical solutions in embodiments of the invention will be clearly and completely described below in conjunction with the accompanying drawings in the embodiments of the invention. Obviously, the described embodiments are only part, not all of the embodiments of the invention. All other embodiments obtained by a person of ordinary skill in the art based on the embodiments of the invention without creative efforts shall fall within the scope of the invention. Referring to FIG. 1 and FIG. 2, a multi-wafer scrubbing device comprises a box body 1.

Multiple compartments 2 are provided in the box body 1. The bottoms of the multiple compartments 2 are connected and the multiple compartments 2 share a drainage system. The tops of the multiple compartments 2 are connected and the multiple compartments 2 share an exhaust system 21. A support wheel system 3 and a scrubbing system 4 are provided inside each compartment 2, and the support wheel system 3 is configured to place wafers 6 by means of support wheels, to fix the position of the wafers 6, and to drive the wafers 6 to rotate during the scrubbing process. Each compartment 2 is internally provided with a spray system 22, and when there are wafers 6 inside the box body 1, the spray system 22 continuously sprays cleaning liquid to clean the chemical reagents away from the surfaces of the wafers 6.

The scrubbing system 4 comprises a group of roller brush units 5, and the roller brush units 5 can get close to each other to scrub the wafers 6 or away from each other to take out the wafers 6. Multiple scrubbing systems are connected by means of an opening and closing drive mechanism 7, and the opening and closing drive mechanism 7 is used for simultaneously driving multiple groups of roller brush units 5 to get close to or away from each other.

The roller brush units 5 may get close to or away from each other in translation. They may also open at one end to get away from each other, or close at one end to get closer to each other.

The roller brush unit 5 comprises two crossbars 53 arranged in parallel, two first connecting plates 51 connected to two ends of one crossbar 53, and two second connecting plates 52 connected to two ends of the other crossbar 53. The space between the two first connecting plates 51 and between the two second connecting plates 52 is used to install roller brushes 54. The two first connecting plates 51 connected to the crossbar 53 are symmetrically arranged to ensure the parallelism of the roller brushes 54 when the roller brushes 5 move to open or close.

In order to avoid interference, the two crossbars 53 are installed in different positions. One of the crossbars 53 is installed between the bottoms of the two first connecting plates 51. specifically, between the sides of the bottoms away from the second connecting plates 52 of the same group of roller brush units 5. The other crossbar 53 is installed between middle parts of the two second connecting plates 52, specifically between the sides of the middle parts away from the first connecting plates 51 of the same group of roller brush units 5.

Driven by the opening and closing drive mechanism 7, the two first connecting plates 51 and the two second connecting plates 52 of different groups of roller brush units 5 (i.e., the roller brush units 5 in different compartments 2) are opened or closed in a V-shape simultaneously.

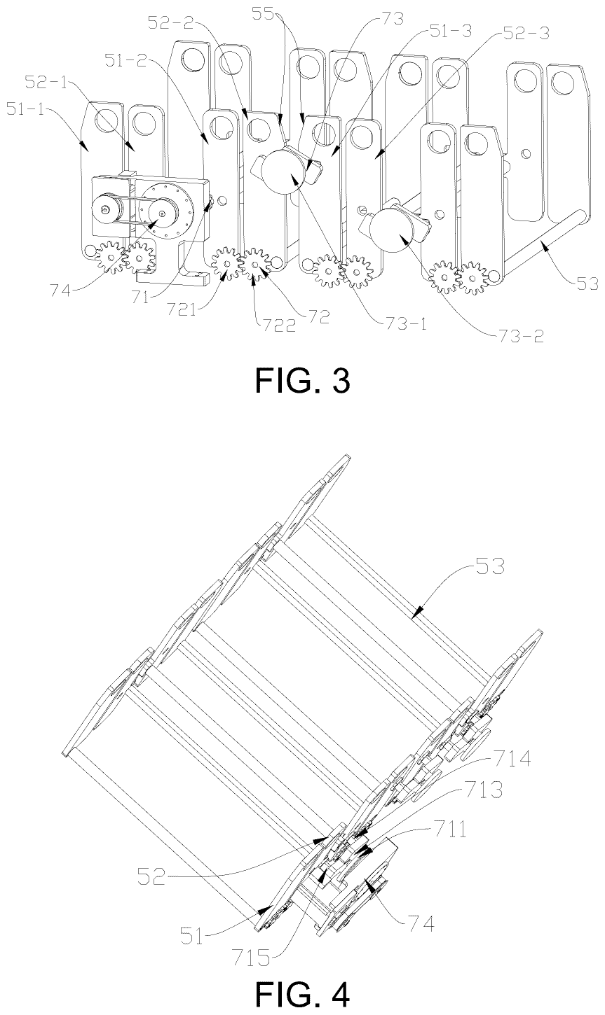

Referring to FIG. 3 and FIG. 4, the opening and closing drive mechanism 7 comprises a power source 74, a first driving unit 71 connected to the power source 74, a second driving unit 72, and a third driving unit 73. The first driving unit 71 is respectively connected to the second connecting plates 52 and the first connecting plates 51 of an adjacent roller brush unit 5. The second driving unit 72 is configured to drive the first connecting plates 51 and the second connecting plates 52 of the same group of roller brush units 5 to open or close. The third driving unit 73 is provided between adjacent rolling brush units 5 that are not connected to a power source and is configured to drive the second connecting plates and the first connecting plates of the adjacent rolling brush units 5 to open or close.

The first driving unit 71 at least comprises a turntable 711 that can be driven by the power source 74 to rotate circumferentially, and connecting rods 712. Two connecting rods 712 are provided. One ends of the two connecting rods 712 are directly or indirectly connected to the turntable 711. The other ends of the two connecting rods 712 are directly or indirectly connected to the first connecting plates and the second connecting plates of the adjacent roller brush unit 5 respectively.

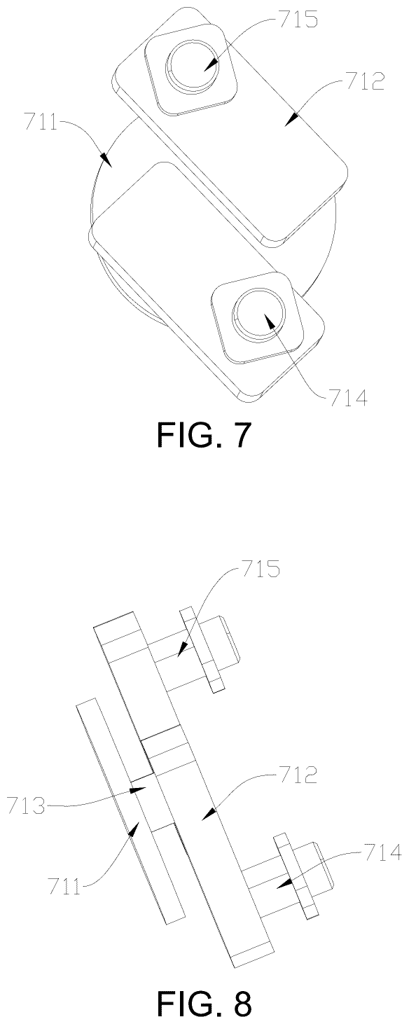

Referring to FIG. 6 to FIG. 8, in this embodiment, each of the two connecting rods 712 and the turntable 711 are connected by means of a third transfer column 713, and the two third transfer columns 713 are arranged in a radial direction of the turntable 711. In an initial state, the two third transfer columns 713 are located vertically between the two connecting plates to facilitate subsequent transmission. So the transmission structure more labor-saving. The connecting rods 712 and the third transfer columns 713 are connected obliquely, and the two connecting rods 712 are arranged in parallel. The first connecting plate and one connecting rod 712 are connected by means of a first transfer column 714. The second connecting plate of the other roller brush unit 5 and the other connecting rod 712 are connected by means of a second transfer column 715.

The connection between the connecting rods 712 and the third transfer columns 713 may be a rotational connection or a fixed connection; the connection between the connecting rod 712 and the first transfer column 714 may be a rotational connection or a fixed connection; the connection between the connecting rod 712 and the second transfer column 715 may be a rotational connection or a fixed connection; the connection between the first transfer column 714 and the first connecting plate may be a rotational connection or a fixed connection; the connection between the second transfer column 715 and the second connecting plate may be a rotational connection or a fixed connection. However, the connections among the two connecting rods 712. the third transfer columns 713, the first transfer column 714, the second transfer column 715, the first connecting plate and the second connecting plate cannot all be fixed connections, but at least one of the connections in the connection structure on one side is rotational connection.

The second driving unit 72 comprises a first gear 721 provided at the bottom of the first connecting plate 51 and a second gear 722 provided at the bottom of the second connecting plate 52. The first gear 721 and the second gear 722 mesh with each other for transmission. The first connecting plate 51 and the second connecting plate 52 belong to the same group of roller brush units 5. Of course, in other embodiments, the second driving unit 72 is not limited to gear transmission, and may also be in the form of belt transmission, connecting rod transmission, etc.

The structure of the third driving unit 73 is the same as that of the first driving unit 71. except that the turntable is not in a rotational connection with the power source. In a case where at least two third driving units 73 are provided, the at least two third driving units 73 are arranged one above the other alternately.

In order to form an avoidance space and avoid interference between adjacent roller brush units 5, notches 55 are formed in both the second connecting plates and the first connecting plates. Specifically, a cut notch is formed at the top of one side the second connecting plate facing the first connecting plate of the other roller brush unit and a cut notch is also formed at the top of one side of the first connecting plate facing the second connecting plate of the other roller brush unit.

The working process of the invention is described by taking FIG. 3 as an example. The power source 74 drives the turntable 711 of the first driving unit 71 to rotate counterclockwise, and then the two connecting rods 712 are driven to rotate, thereby causing the top of the second connecting plate 52-1 and the top of the first connecting plate 51-2 to open, where the second connecting plate 52-1 and the first connecting plate 51-2 belong to two different roller brush units 5.

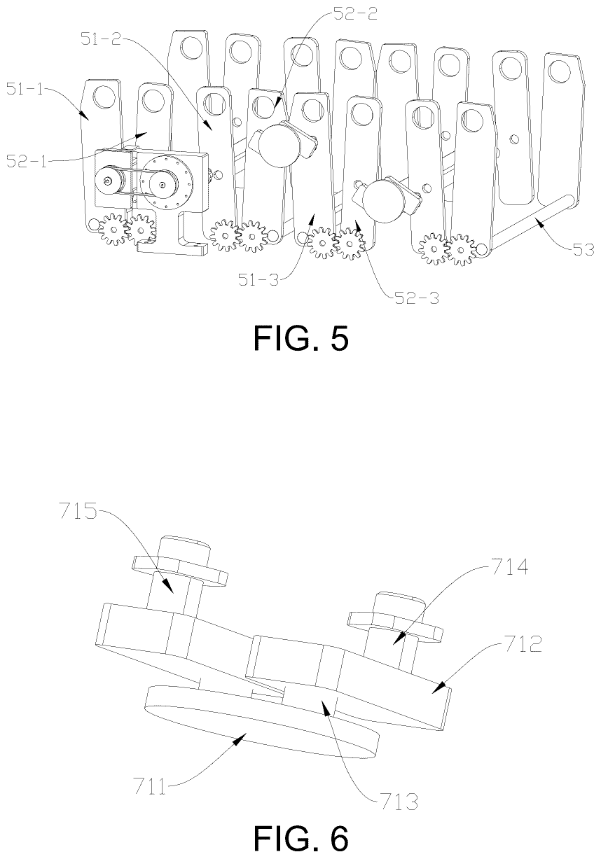

At the same time, driven by the second driving unit 72 at the bottom of a first group of roller brush units, that is, by virtue of meshing transmission of the first gear at the bottom of the first connecting plate 51-1 and the second gear at the bottom of the second connecting plate 52-1, the first connecting plate 51-1 and the second connecting plate 52-1 of the first group of rolling units are opened in a V-shape, as shown in FIG. 5. The second connecting plate 52-1 and the first connecting plate 51-2 described here belong to the same group of roller brush units 5.

Similarly, the first connecting plate 51-2 and the second connecting plate 52-2 of a second group of roller brush units are also opened in a V-shape.

Driven by the second connecting plate 52-2, the second transfer column of the third driving unit 73 rotates, thereby causing the first connecting plate 51-3 of a third group of roller brush units to rotate. Driven by another second driving unit, the first connecting plate 51-3 and the second connecting plate 52-3 of the third group of roller brush units are also opened in a V-shape.

Another third driving unit is connected between the third group of roller brush units and a fourth group of roller brush units, and in this case, the third driving unit is located at a lower position in the middle, which is different from the one between the second group of roller brush units and the third group of roller brush units which is located at the upper position in the middle. That is, in the case where at least two third driving units are provided, the at least two third driving units are arranged one above the other alternately.

The scrubbing system 4 controls the opening, closing and rotation of the roller brush units 5. In the initial stage of brushing, the opening and closing drive mechanism 7 controls the roller brush units 5 to open to form a gap large enough for a robot arm to extend into the box body 1 without interference.

The above is the process of opening the first connecting plates and the second connecting plates. After the first connecting plates and the second connecting plates are opened, robot arms are used to clamp the wafers 6. After the robot arms are lifted and moved out of the box body 1, the first connecting plates and the second connecting plates need to be closed to bring the roller brushes 54 close to the wafers 6 to scrub the wafers 6, so the power source 74 is used to drive the turntable 711 of the first driving unit 71 to rotate clockwise.

The roller brushes 54 continue to rotate and at the same time move close to the middle to clamp the wafers 6. The roller brushes on the left rotate clockwise and the roller brushes on the right rotate counterclockwise, ensuring that the wafers receive a downward resultant force during the scrubbing process. The roller brushes work together with the support wheel system 3 to fix the position of the wafers. The support wheel system 3 drives the wafers to rotate in a fixed direction to ensure that the roller brushes can scrub every surface of the wafers. Cleaning liquid sprayed from different compartments 2 is collected in the space at the bottom of the box body 1 and discharged to the outside of equipment along the same set of drainage pipelines.

The above specific embodiments are used to explain the invention, rather than to limit the invention. Within the spirit of the invention and the scope of the claims, any modifications and changes made to the invention will fall within the scope of the invention.

1. A multi-wafer scrubbing device, comprising a box body (1), wherein multiple compartments (2) are provided in the box body (1); bottoms of the multiple compartments (2) are connected, a support wheel system (3) and a scrubbing system (4) are provided inside each compartment (2), the scrubbing system (4) comprises a group of roller brush units (5), and the roller brush units (5) can get close to each other to scrub wafers (6) or away from each other to take out the wafers (6); the multiple scrubbing systems (4) are connected by means of an opening and closing drive mechanism (7); the opening and closing drive mechanism (7) is used for simultaneously driving the multiple groups of roller brush units (5) to get close to or away from each other.

2. The multi-wafer scrubbing device according to claim 1, wherein the roller brush unit (5) comprises two crossbars (53) arranged in parallel, first connecting plates (51) connected to two ends of one crossbar (53), and second connecting plates (52) connected to two ends of the other crossbar (53), and the first connecting plates (51) and the second connecting plates (52) are configured to install roller brushes (54); driven by the opening and closing drive mechanism (7), the two first connecting plates (51) and the two second connecting plates (52) of different groups of roller brush units (5) are all opened or closed in a V-shape synchronously.

3. The multi-wafer scrubbing device according to claim 2, wherein the opening and closing drive mechanism (7) comprises a power source (74), a first driving unit (71) connected to the power source (74), a second driving unit (72), and a third driving unit (73); the first driving unit (71) is respectively connected to the second connecting plates and the first connecting plates of the adjacent roller brush unit (5); the second driving unit (72) is configured to drive the first connecting plates and the second connecting plates of the same group of roller brush units (5) to open or close; the third driving unit (73) is provided between adjacent rolling brush units (5) that are not connected to the power source and is configured to drive the second connecting plates and the first connecting plates of the adjacent rolling brush units (5) to open or close.

4. The multi-wafer scrubbing device according to claim 3, wherein the first driving unit (71) at least comprises a turntable (711) that is driven by the power source (74) to rotate circumferentially, and connecting rods (712); two connecting rods (712) are provided, one ends of the two connecting rods (712) are directly or indirectly connected to the turntable (711), and the other ends of the two connecting rods (712) are directly or indirectly connected to the first connecting plates and the second connecting plates of the adjacent roller brush unit (5) respectively.

5. The multi-wafer scrubbing device according to claim 4, wherein each of the two connecting rods (712) and the turntable (711) are connected by means of a third transfer column (713), the first connecting plate and one connecting rod (712) are connected by means of a first transfer column (714), and the second connecting plate and the other connecting rod (712) are connected by means of a second transfer column (715).

6. The multi-wafer scrubbing device according to claim 5, wherein the two third transfer columns (713) are arranged in a radial direction of the turntable (711); in an initial state, the two third transfer columns (713) are located vertically between the two connecting plates, and the connecting rods (712) and the third transfer columns (713) are connected obliquely.

7. The multi-wafer scrubbing device according to claim 3, wherein the second driving unit (72) comprises a first gear (721) provided at a bottom of the first connecting plate (51) and a second gear (722) provided at a bottom of the second connecting plate (52), and the first gear (721) and the second gear (722) mesh with each other for transmission.

8. The multi-wafer scrubbing device according to claim 3, wherein in a case where the at least two third driving units (73) are provided, the at least two third driving units (73) are arranged one above the other alternately.

9. The multi-wafer scrubbing device according to claim 2, wherein notches (55) are formed in both the second connecting plates and the first connecting plates of the adjacent roller brush units (5) to form an avoidance space.

10. The multi-wafer scrubbing device according to claim 1, wherein tops of the multiple compartments (2) are connected and the multiple compartments (2) share an exhaust system (21) and a drainage system; each compartment (2) is internally provided with a spray system (22).
